(19) United States
(12) Patent Application Publication
(10) Pub. No.: US 2025/0324792 A1
(43) Pub. Date: Oct. 16, 2025

(54) IMAGE SENSOR AND ITS MANUFACTURING METHOD

(71) Applicant: STMicroelectronics International N.V., Geneva (CH)

(72) Inventors: Pierre BAR, Grenoble (FR); Claire GALLON, Pontcharra (FR); Maxime REGE TURO, Grenoble (FR); Pascal GOURAUD, Montbonnot St Martin (FR)

(73) Assignee: STMicroelectronics International N.V., Geneva (CH)

(21) Appl. No.: 19/098,263

(22) Filed: Apr. 2, 2025

(30) Foreign Application Priority Data
Apr. 11, 2024 (FR) FR2403720

(51) Int. Cl. H10F 39/00; H10F 39/18

(52) U.S. Cl. CPC H10F 39/8053; H10F 39/014; H10F 39/024; H10F 39/182; H10F 39/8063; H10F 39/811

(57) ABSTRACT

The present description concerns an image sensor comprising a semiconductor substrate comprising a first surface, a porous layer, made of an electrically-insulating and porous material, on the first surface crossed by openings, a color filter in each opening, a first moisture-proof protection layer covering the porous layer outside of the openings, and a second moisture-proof protection layer covering the covering the first protection layer and the walls of each opening, between the porous layer and the color filter present in the opening.

### CROSS-REFERENCE TO RELATED APPLICATION(S)

This application claims the priority benefit of French patent application number 24/03720, filed on Nov. 4, 2024, entitled “Capteur d'images et son procédé de fabrication,” which is hereby incorporated by reference to the maximum extent allowable by law.

### BACKGROUND

### Technical Field

The present disclosure generally concerns the field of image sensors and image sensor manufacturing methods.

### Description of the Related Art

An image sensor generally comprises a plurality of photodetectors, for example, photodiodes, integrated inside and on top of a semiconductor substrate.

Image sensors having their photodetectors topped by color filters or infrared filters are here more particularly considered. Each color filter enables to filter according to the wavelength the radiation that reaches the photodetector topped by the color filter. The image sensor may comprise walls surrounding the color filters to decrease the optical crosstalk between photodetectors. The walls may be partly metallic. However, the walls tend to absorb part of the incident photons. This causes a drop in the optical efficiency of the image sensor, and this, all the more strongly as the dimensions of the photodetectors and of the color filters are small.

It would be desirable to at least partly improve certain aspects of known methods of manufacturing an image sensor comprising color filters surrounded by walls.

### BRIEF SUMMARY

An embodiment overcomes all or part of the disadvantages of known image sensors comprising color filters surrounded by walls.

An embodiment provides an image sensor comprising:
a semiconductor substrate comprising a first surface;
a porous layer, made of an electrically-insulating and porous material, on the first surface, crossed by openings;
a color filter in each opening;
a first moisture-tight protection layer covering the porous layer outside of the openings; and
a second moisture-tight protection layer covering the first protection layer and the walls of each opening, between the porous layer and the color filter present in the opening.

According to an embodiment, the porosity by volume of the porous material is in the range of 35% and 55%.

According to an embodiment, the porous layer comprises a through groove completely surrounding the openings, the second protection layer covering the walls of the groove.

According to an embodiment, the image sensor further comprises:
a plurality of photodetectors inside and on top of the semiconductor substrate, the color filters covering the photodetectors;
a plurality of microlenses covering the color filters; and
a third protection layer on the plurality of microlenses and on the first and second protection layers around the plurality of microlenses.

According to an embodiment, the semiconductor substrate comprises a second surface opposite to the first surface and at least one hole extending from the first surface to the second surface, the image sensor further comprising an electrically-conductive pad comprising a first portion extending over the first surface and a second portion covering the flanks of the hole and delimiting a gap in the hole.

According to an embodiment, the image sensor further comprises a guard ring and the electrically-conductive pad forms part of the guard ring.

According to an embodiment, the thickness of the porous layer is in the range of 400 nm and 900 nm.

An embodiment also provides a method of manufacturing an image sensor comprising the following steps:
a) forming a porous layer, made of a porous electrically-insulating material, on a first surface of a semiconductor substrate;
b) forming a first moisture-tight protection layer covering the porous layer;
c) forming openings running through the first protection layer and the porous layer;
d) forming a second moisture-tight protection layer covering the first layer and the walls of each opening; and
e) forming a color filter in each opening, the second protection layer being located between the porous layer and the color filter present in the opening.

According to an embodiment, the method further comprises, at step c), the forming of a through groove in the porous layer totally surrounding the openings, the second protection layer further covering at step d) the walls of the groove.

According to an embodiment, the method further comprises the following steps:
prior to step a), the forming of a plurality of photodetectors inside and on top of the semiconductor substrate, the color filters being formed at step e) covering the photodetectors;
forming a plurality of microlenses covering the color filters; and
forming a third protection layer over the plurality of microlenses and over the first and second protection layers around the plurality of microlenses.

According to an embodiment, the semiconductor substrate comprises a second surface opposite to the first surface, the method further comprising the forming, prior to step a), of a hole extending from the first surface to the second surface and of an electrically-conductive pad comprising a first portion extending over the first surface and a second portion covering the flanks of the hole and delimiting a gap in the hole.

According to an embodiment, the method further comprises, prior to step a), the forming of a resin block in the gap, the porous layer covering the electrically-conductive pad and the resin block, and, after step e), the successive etching of the first protection layer, of the second protection layer, and of the porous layer to expose the electrically-conductive pad and the resin block, and the removal of the resin block.

According to an embodiment, the method further comprises the forming of a guard ring, the electrically-conductive pad forming part of the guard ring.

### BRIEF DESCRIPTION OF THE SEVERAL VIEWS OF THE DRAWINGS

The foregoing features and advantages, as well as others, will be described in detail in the rest of the disclosure of specific embodiments given as an illustration and not limitation with reference to the accompanying drawings, in which:

FIG. 1, FIG. 2, FIG. 3, FIG. 4, FIG. 5, FIG. 7, FIG. 8, FIG. 9, FIG. 10, FIG. 11, FIG. 12, FIG. 13, FIG. 14, FIG. 15, and FIG. 16 are partial and simplified cross-section views of structures obtained at the end of successive steps of an embodiment of an image sensor manufacturing method, and FIG. 6 is a partial and simplified top view of the structure of FIG. 5;

FIG. 17 is a partial and simplified cross-section view of another embodiment of an image sensor; and

FIG. 18 is a partial and simplified cross-section view of an example of an image sensor.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the design of the photodetectors of the described image sensors, as well as of their control circuits, has not been detailed, the design of these elements being within the abilities of those skilled in the art based on the indications of the present disclosure.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front,” “back,” “top,” “bottom,” “left,” “right,” etc., or relative position qualifiers, such as “top,” “bottom,” “upper,” “lower,” etc., or orientation qualifiers, such as “horizontal,” “vertical,” etc., reference is made unless otherwise specified to the orientation of the drawings.

Unless specified otherwise, the expressions “about,” “approximately,” “substantially,” and “in the order of” signify plus or minus 10%, preferably of plus or minus 5%. Further, it is here considered that the terms “insulating” and “conductive” respectively mean “electrically insulating” and “electrically conductive.”

An embodiment of a method of manufacturing an electronic circuit corresponding to an image sensor will now be described. Generally, this embodiment of a manufacturing method may be implemented for any type of electronic circuit comprising color filters. In the following description, the refractive index of a material corresponds to the refractive index of the material for the wavelength range of the radiation captured by the image sensor. Unless otherwise specified, the refractive index is considered to be substantially constant over the wavelength range of the radiation captured by the image sensor, for example equal to the average of the refractive index over the wavelength range of the radiation captured by the image sensor.

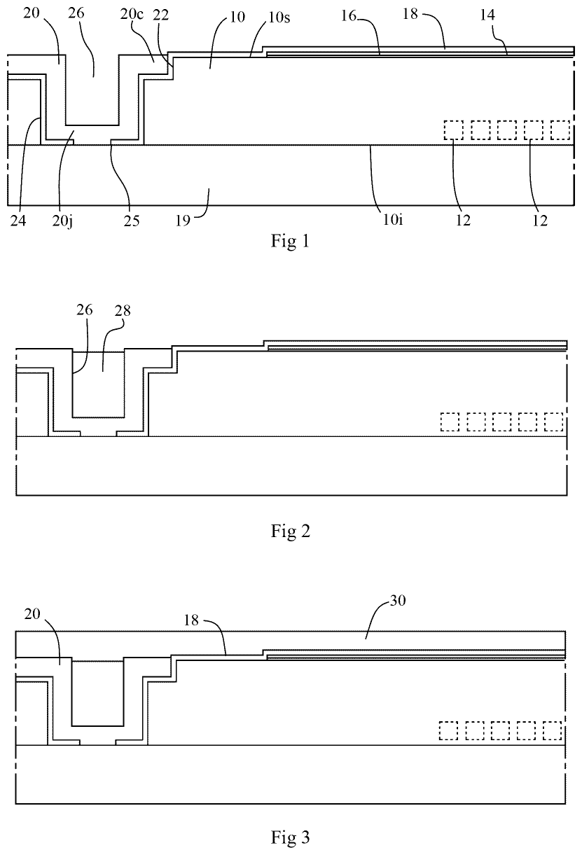

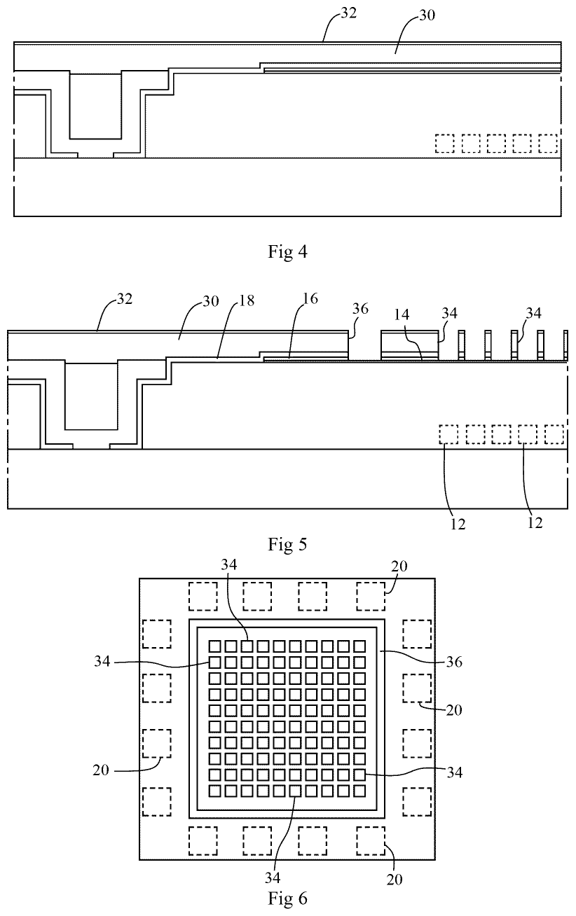

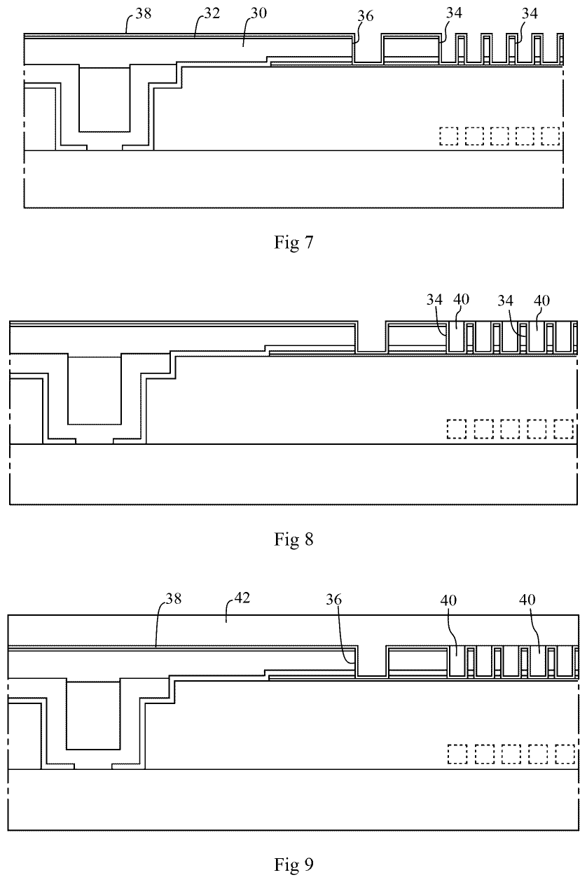

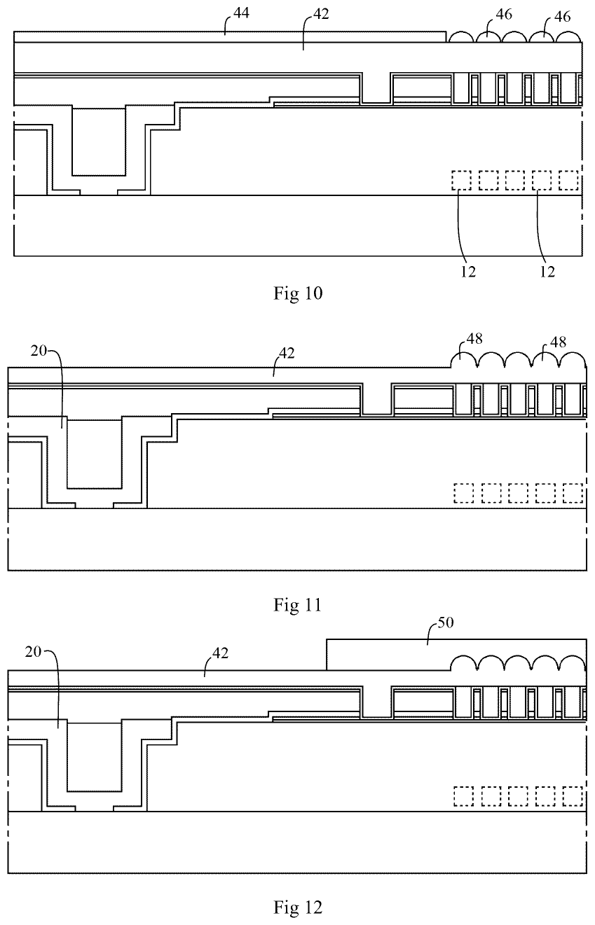

FIGS. 1 to 16 illustrate, partially and schematically, structures obtained at the end of successive steps of an image sensor manufacturing method.

More particularly, FIG. 1 corresponds to an initial structure comprising a semiconductor substrate 10, for example a silicon substrate, in which photodetectors 12 have been previously formed, five photodetectors 12 being shown in dotted lines in FIG. 1. As an example, photodetectors 12 are photodiodes, for example, adapted to capturing infrared, visible, and/or ultraviolet radiation. As an example, photodetectors 12 are photodetectors made in CMOS (Complementary Metal Oxide Semiconductor) technology. According to an embodiment, photodetectors 12 are arranged in rows and columns, the pitch between adjacent photodetectors being in the range from 30 nm to 2 μm.

Substrate 10 comprises an upper surface 10s and a lower surface 10i, opposite to upper surface 10s. Part of the upper surface 10s is covered by an insulating layer 14, itself covered by an opaque screen 16. An insulating layer 18 covers opaque screen 16 and the rest of upper surface 10s around opaque screen 16. Substrate 10 is covered, on the side of lower surface 10i, by an interconnection structure 19, comprising a stack of insulating layers having conductive tracks, not shown, extending therebetween and having conductive vias, not shown, extending therethrough. According to an embodiment, substrate 10 has a thickness in the range from 3 μm to 10 μm. Opaque screen 16 is intended, in operation, to block the light radiation received by the structure to protect electronic components present in substrate 10 other than photodetectors 12. Opaque screen 16 may be metallic. Opaque screen 16 may have a single-layer or multilayer structure. For example, opaque screen 16 may comprise a layer of tungsten (W) and/or a layer of titanium (TiN). According to an embodiment, opaque screen 16 has a thickness in the range of 150 nm and 400 nm. Insulating layer 14 and insulating layer 18 may each be made of silicon oxide (SiO₂) or of silicon nitride (SiN). Similarly, a stack of anti-reflective materials may form this layer. According to an embodiment, insulating layer 14 has a thickness in the range from 50 nm to 250 nm. According to an embodiment, insulating layer 18 has a thickness in the range from 100 nm to 550 nm.

In this example, substrate 10 is intended to be illuminated on upper surface 10s. The initial structure further comprises one or a plurality of contacting pads 20, a single contacting pad 20 being shown in FIG. 1. According to an embodiment, contacting pad 20 is electrically insulated from substrate 10 by insulating layer 18. Pads 20 are arranged out of line with photodetectors 12 in order not to mask photodetectors 12. As an example, in top view, photodetectors 12 are located in a central region of substrate 10, and pads 20 are located opposite a peripheral region of substrate 10. According to an embodiment, opaque screen 16 covers photodetectors 12 as well as part of the surface 10s of substrate 10 between photodetectors 12 and pads 20.

Each contacting pad 20 comprises a contact area 20c which extends in a recess 22 provided in the upper surface 10s of substrate 10. The contact area 20c of each pad 20 is intended to be connected to an external device, for example by means of an electrically-conductive wire, for example a metal wire. Substrate 10 comprises, for each pad 20, a through opening 24 which extends from the upper surface 10s to the lower surface 10i. Opening 24 emerges into recess 22. According to an embodiment, the upper surface 10s is planar outside of recesses 22 and of through openings 24. According to an embodiment, opening 24 has a substantially constant cross-section, as seen in a direction perpendicular to surface 10s. As an example, the cross-section of opening 24 is square or rectangular, in particular inscribed within a rectangle having its short side length varying from 2 μm to 15 μm and having its long side length varying from 10 μm to 50 μm. Contacting pad 20 comprises a junction portion 20j which extends in through opening 24. As an example, the junction portion 20j of contacting pad 20 is connected to one or a plurality of metallization levels of interconnection structure 19 arranged on the side of the lower surface 10i of substrate 10 through an opening 25 in insulating layer 18. As an example, contacting pads 20 are made of a metallic material, for example of aluminum. Junction portion 20j covers the sides of opening 24. However, opening 24 is not totally filled by junction portion 20j, so that an air-filled gap 26, emerging onto the outside, remains in opening 24. As an example, junction portion 20j has a thickness, measured with respect to the flanks of opening 24, which is in the range from 100 nm to 2 μm, and is for example equal to approximately 1 μm. As an example, the depth of gap 26 is in the range from 2.5 μm to 15 μm, and is for example equal to approximately 6 μm.

As an example, contacting pads 20 may be used for the signals exchange with the image sensor and/or for the electrical power supply of the image sensor. According to another example, one of contacting pads 20 may form part of a protection structure such as a guard (or seal) ring, in which case the pad may extend around the entire periphery of the image sensor.

FIG. 2 illustrates the structure obtained at the end of a step of forming of a resin block 28 in the gap 26 of each contact pad 20. According to an embodiment, this step of forming of resin block 28 is carried out by means of specific developable resins known to those skilled in the art as “BSI fill” resins.

FIG. 3 illustrates the structure obtained at the end of a step of forming of a layer 30 of a material having a low refractive index on insulating layer 18 outside of the contacting pads 20 and on contacting pads 20. According to an embodiment, the refractive index of the material forming layer 30 is in the range from 0.5 to 1.35. According to an embodiment, the thickness of layer 30 is in the range of 400 nm and 900 nm. According to an embodiment, layer 30 is made of a porous material and is called porous layer hereafter. The porosity of a material is equal to the proportion by volume of pores in a given volume of the material comprising both the solid part and the pores. According to an embodiment, the porosity of layer 30 is in the range of 35% and 55%, preferably from 40% to 50%, for example equal to approximately 45%. According to an embodiment, the pore size is equal to approximately 5 nm. According to an embodiment, the pores of layer 30 are filled with vacuum or with a gas mixture. According to an embodiment, layer 30 comprises as an essential constituent material at least one compound from among silicon or carbon. Porous layer 30 may correspond to a single oxide or to a mixed oxide of at least one of the above-mentioned elements. Preferably, porous layer 30 is made of silicon oxide obtained by annealing above 200° C.

According to an embodiment, porous layer 30 is formed either by a method known to those skilled in the art under the name spin coating, followed by an anneal, or deposition of low-permittivity oxide. According to an embodiment, the method of manufacturing porous layer 30 comprises the deposition of a solution on the structure of FIG. 2, for example by a spin-coating technique, the solution comprising a precursor of the material forming porous layer 30, in particular a hydrolyzable compound such as a silicon halide or alkoxide, in at least one solvent, in particular aqueous and/or alcoholic. The method then comprises the condensation of the precursor to form the solid material of porous layer 30 and for the removal of the solvent.

FIG. 4 illustrates the structure obtained after a step of forming of a protection layer 32 on porous layer 30. According to an embodiment, the thickness of protection layer 32 is in the range from 20 nm to 50 nm. According to an embodiment, protection layer 32 is made of silicon oxide deposited at low temperature, for example at 150° C.

FIG. 5 illustrates the structure obtained at the end of a step of forming of openings 34 and of a groove 36 through protection layer 32, porous layer 30, insulating layer 18, and opaque screen 16 and a portion of layer 14. FIG. 6 is a top view of the structure of FIG. 5.

Openings 34 are formed vertically in line with photodetectors 12. As an example, openings 34 are arranged in rows and columns at the center of the structure. According to an embodiment, groove 36 totally surrounds all openings 34. Contacting pads 20, schematically shown in dotted lines in FIG. 6, are located around groove 36. According to an embodiment, the aspect ratio of each opening 34, corresponding to the ratio of the height to the width of opening 34, is in the range from 0.6 to 1.2. As an example, the cross-section of each opening 34, along a direction perpendicular to surface 10s, is square or rectangular, in particular inscribed within a rectangle having its short side length varying from 0.5 μm to 2 μm and having its long side length varying from 1 μm to 10 μm. According to an embodiment, the width of groove 36 is in the range from 1 μm to 20 μm.

Preferably, openings 34 and groove 36 are formed simultaneously. According to an embodiment, openings 34 and groove 36 are formed by reactive ion etching (RIE). The presence of protection layer 32 enables to implement photolithography steps which could not be directly implemented on porous layer 30 due to its high porosity. Similarly, this protection layer 32 has the advantage of authorizing possible steps of wafer rework steps in the successive photolithography steps. An advantage of this method is the simultaneous etching of layers 30 and 32 without altering the integrity of pad 20.

FIG. 7 illustrates the structure obtained at the end of a step of forming of a protection layer 38 on protection layer 32 outside of openings 34 and of groove 36 and in each opening 34 and in groove 36, protection layer 38 covering the side walls of each opening 34 and of groove 36 and the bottom of each opening 34 and of groove 36. According to an embodiment, the thickness of protection layer 38 is in the range from 5 nm to 60 nm. Protection layer 38 is moisture-tight. According to an embodiment, protection layer 38 is made of silicon oxide or of aluminum oxide. Since groove 36 totally surrounds openings 34 and protection layer 38 covers porous layer 30, the walls of groove 36, and the walls of each opening 34, protection layer 38 prevents moisture from reaching the portion of porous layer 30 having openings 34 formed therein. In the absence of groove 36, having its walls covered by protection layer 38, moisture might penetrate into the portion of porous layer 30 having openings 34 formed therein, particularly from the edge of porous layer 30, and the presence of moisture would cause an increase and/or a lack of uniformity of the refractive index of carrier layer 30. Similarly, the presence of moisture can lead to problems of reliability of optical sensors.

FIG. 8 illustrates the structure obtained at the end of a step of forming of color filters 40 in openings 34. Color filters 40 may correspond to colored resin blocks. Color filters 40 of different colors may be present. According to an embodiment, color filters 40 of a same type are formed by the deposition of a layer of colored resist over the entire structure and in particular in openings 34, the exposure of the colored resist layer to radiation, and the removal of the portions of the resist layer exposed to radiation in the case of a positive resist or not exposed to radiation in the case of a negative resist, to keep the colored resist blocks in the desired openings 34. These steps are repeated for each type of color filter 40.

FIG. 9 illustrates the structure obtained at the end of a step of forming of a resin layer 42 on protection layer 38 and on color filters 40. Resin layer 42 totally fills, in particular, groove 36. Resin layer 42 has a thickness in the range from 0.6 μm to 4 μm, for example, in the order of 4 μm. The resin of layer 42 is, for example, a crosslinked resin which cannot be dissolved in usual liquid resin developing and/or etching solvents. The resin of layer 42 is, for example, a non-photosensitive resin. As an example, the resin of layer 42 is selected so that it can be crosslinked, for example by ultraviolet light or from a certain temperature, for example, in the order of 200° C. As an example, the resin of layer 42 is selected so that it can be etched by means of an oxygen-based physical plasma. As an example, the resin of layer 42 comprises a polymer, for example of acrylic type.

FIG. 10 illustrates the structure obtained at the end of a step of forming of an etch mask 44 on the upper surface of resin layer 42. Mask 44 comprises microlens-shaped structures, intended to be transferred into the resin layer 42 during a subsequent etch step, to form microlenses in layer 42.

As an example, mask 44 is formed from a resist layer. The resin of mask 44 is, for example, first deposited over the entire wafer, on top of and in contact with the upper surface of layer 42. At this stage, the resin of mask 44 for example has a substantially uniform thickness over the entire surface of the structure. The deposition of the resin of mask 44 may be performed by a spin-coating technique or by any other adapted deposition technique. The resin layer of mask 44 is then structured, for example by photolithography, to form, in front of photodetectors 12, separate resin pads 46. In this example, an individual resin pad 46 is provided in front of each photodetector 12 of the sensor. A flow anneal is then implemented, during which resin pads 46 are deformed to take the shape of microlenses. After the flowing, resin pads 46 are for example separate. The described embodiments are however not limited to this specific case. Pads 46 for example have a thickness smaller than the thickness of layer 42.

FIG. 11 illustrates the structure obtained at the end of a step of physical etching of layer 42 and of mask 44, resulting in transferring the pattern of mask 44 to an upper portion of layer 42. The etching is for example stopped when all the resin of mask 44 has been consumed.

Thus, in the structure illustrated in FIG. 11, layer 42 comprises microlenses 48 facing photodetectors 12. As an example, microlenses 48 have a height in the range from 0.5 μm to 3 μm. At this stage, connection pads 20 remain covered with the resin of layer 42.

FIG. 12 illustrates a device obtained at the end of a step of forming of a masking layer 50 made of resin on the upper surface of layer 42.

As an example, layer 50 is first deposited all over the wafer on the upper surface of layer 42, for example in contact with the upper surface of layer 42. Layer 50 is then removed, for example by photolithography, opposite pads 20, to expose the portion of resin layer 42 coating pads 20. The resin of layer 50 is, for example, resist. As an example, layer 50 has a thickness greater than the maximum thickness of layer 42. As an example, layer 50 has a thickness in the range from 4 μm to 10 μm, for example in the order of 6 μm.

FIG. 13 illustrates the structure obtained at the end of a step of etching of layer 42 through layer 50. During this step, layer 50 is used as an etch mask.

More particularly, during this step, the portion of layer 42 not covered by layer 50 is removed to expose protection layer 38. Protection layer 38 may act as an etch stop layer.

According to an embodiment, the etching implemented during this step is a totally chemical, and thus isotropic, plasma etching (method sometimes designated with the terms “dry-stripping” or “dry-ashing”). This chemical etching is based on the use of free radicals generated by remote plasmas. This etching technique is currently used to remove, recycle, or strip resin layers from the entire wafer surface. This technique is further sometimes used to perform, over an entire wafer surface, chemical treatments on exposed materials. It is here proposed to use it, uncommonly, to perform a local etching of resin layer 42 through the mask formed by resin layer 50. This technique has the advantage of being less aggressive than a physical etching, and does not generate polymer fibers or filaments on the flanks of layer 42.

According to another embodiment, the etching implemented during this step is an etching by plasma ion bombardment, also known as reactive dry etching or dry etching. Such an etching causes a removal of material by bombardment.

The etch plasma preferably comprises oxygen, nitrogen, and hydrogen. The plasma used during this etch step has, for example, a different composition than the plasma used during the etching leading to the forming of microlenses 48. During the above-mentioned step, layers 50 and 42 are consumed simultaneously.

The above-mentioned etching is stopped when protection layer 38 is exposed. At this stage, a portion of layer 50 remains at the surface of layer 42, particularly on microlenses 48. Resin layer 42 has a lateral flank 51 inclined (not vertical) with respect to surface 10s.

FIG. 14 illustrates a device obtained at the end of a step of removal of the remaining portion of layer 50 to expose the upper surface of microlenses 48. This removal step is for example carried out by wet etching with a solvent, by means of an etch solution enabling to etch the material of layer 50 selectively over the material of layer 42.

FIG. 15 illustrates the structure obtained at the end of a step of deposition of a protection layer 52 made of an electrically-insulating material on the surface of the device illustrated in FIG. 14.

For example, layer 52 extends continuously over the entire upper surface of the device of FIG. 14. Thus, layer 52 particularly covers the microlenses 48 of layer 42 and protection layer 38, particularly on pads 20. As an example, layer 52 is a moisture-tight layer and enables to protect layer 42 from moisture. Layer 52 is, for example, made of an oxide, such as silicon oxynitride (SiON). According to an embodiment, layer 52 is made of the same material as layer 38.

As an example, protection layer 52 is deposited, by a conformal deposition method, on the upper surface of the device illustrated in FIG. 14, for example by chemical vapor deposition, for example a plasma-enhanced chemical vapor deposition (PECVD). Layer 52 has, for example, a thickness in the range from 50 nm to 500 nm, for example in the order of 200 nm. Advantageously, the method of forming layer 52 is the same as that used for the forming of layer 38.

FIG. 16 illustrates the structure obtained at the end of a step of forming of an opening 54 in protection layers 52, 38, and 32 and in porous layer 30 to expose contacting pad 20, and optionally a step of removal of the resin block 28 present in gap 26. Image sensor 60 is thus obtained. According to an embodiment, the material forming resin blocks 28 is the same as that forming resin layer 42 and the method previously described for the removal of resin layer 42 may also be implemented for the removal of resin blocks 28.

Porous layer 30 forms walls 62 separating color filters 40. The refractive index of the material forming walls 62 is lower than the refractive index of the material forming color filters 40. Thereby, walls 62 play the role of a mirror for the light rays crossing color filters 40. In particular, the absorption of light rays by walls 62 is decreased as compared with walls which would be made of metal. Walls 62 advantageously enable to decrease the optical crosstalk between color filters 40 without causing an undesirable absorption of light rays. Indeed, the absorption of photons causes a drop in the optical efficiency of image sensor 60, and this, all the more strongly marked as the dimensions of photodetectors 12 and of color filters 40 are small.

The aspect ratio of walls 62, corresponding to the ratio of the height to the width of wall 62, is in the range from 0.08 to 0.15. According to an embodiment, the height of walls 62 is in the range of 400 nm and 900 nm. According to an embodiment, the width of walls 62 is in the range from 50 nm to 150 nm.

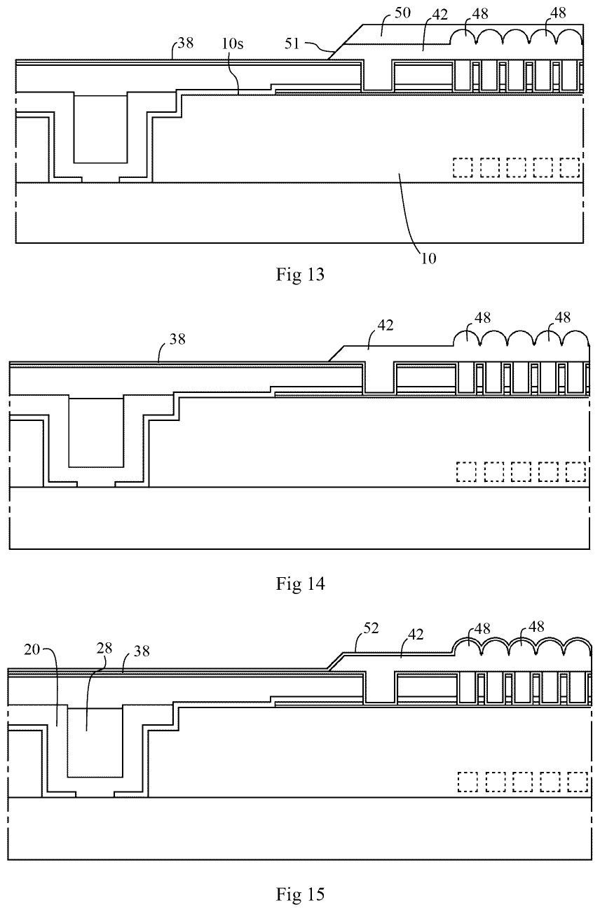

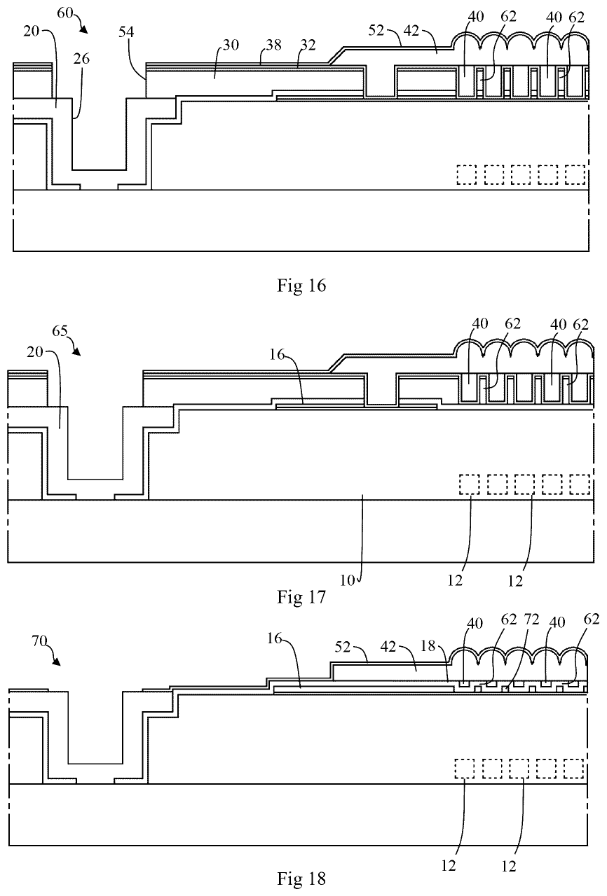

FIG. 17 is a cross-section view of another embodiment of an image sensor 65. The image sensor 65 shown in FIG. 17 comprises all the elements of the image sensor 60 shown in FIG. 16, with the difference that opaque screen 16 is not formed on the portion of substrate 10 comprising photodetectors 12, but only on the portion of substrate 10 between photodetectors 12 and contacting pads 20. The present embodiment enables to further decrease the absorption of light rays, since the material forming opaque screen 16 is not present at the base of walls 62.

FIG. 18 is a cross-section view, partial and simplified, of an example of an image sensor 70 described as a comparison. Image sensor 70 comprises all the elements of the image sensor 60 shown in FIG. 16, with the difference that porous layer 30 is not present and that the walls 62 between color filters 40 are formed by portions 72 of the layer used to form opaque screen 16 and insulating layer 18.

An advantage of image sensor 60 over image sensor 70 is that the absorption of photons in walls 62 is less significant for image sensor 60, which causes an increase in the optical efficiency for image sensor 60. Another advantage is that it is easier to form walls 62 for image sensor 60 with a high aspect ratio.

Various embodiments and variants have been described. Those skilled in the art will understand that certain features of these various embodiments and variants may be combined, and other variants will occur to those skilled in the art. In the previously-described embodiments, groove 36 is filled with the material forming microlenses 48. As a variant, groove 36 may be filled with another material, for example the colored resin used to form one of color filters 40.

Finally, the practical implementation of the described embodiments and variants is within the abilities of those skilled in the art based on the functional indications given hereabove.

An image sensor (60; 65) is summarized as including: a semiconductor substrate (10) including a first surface (10s); a porous layer (30) made of an electrically-insulating and porous material, on the first surface (10s), crossed by openings (34); a color filter (40) in each opening (34); a first moisture-tight protection layer (32) covering the porous layer (30) outside of the openings (34); and a second moisture-tight protection layer (38) covering the first protection layer (32) and the walls of each opening (34), between the porous layer (30) and the color filter (40) present in the opening (34).

The porosity by volume of the porous material may be in the range of 35% and 55%.

The porous layer (30) includes a through groove (36) totally surrounding the openings (34), the second protection layer (38) covering the walls of the groove (36).

The image sensor further include: a plurality of photodetectors (12) inside and on top of the semiconductor substrate (10), the color filters (40) covering the photodetectors (12); a plurality of microlenses (48) covering the color filters (40); and a third protection layer (52) over the plurality of microlenses (48) and over the first and second protection layers (32, 38) around the plurality of microlenses (48).

The semiconductor substrate (10) includes a second surface (10i) opposite to the first surface (10s) and at least one hole (24) extending from the first surface (10s) to the second surface (10i), the image sensor further includes an electrically-conductive pad (20) including a first portion (20c) extending over the first surface (10s) and a second portion (20j) covering the flanks of the hole (24) and delimiting a gap (26) in the hole (24).

The image sensor further includes a guard ring and the electrically-conductive pad (20) may form part of the guard ring.

The thickness of the porous layer (30) is in the range of 400 nm and 900 nm.

A method of manufacturing an image sensor (60; 65) is summarized as including the following steps: a) forming a porous layer (30), made of an electrically-insulating and porous material, on a first surface (10s) of a semiconductor substrate (10); b) forming a first moisture-tight protection layer (32) covering the porous layer (30); c) forming openings (34) running through the first protection layer (32) and the porous layer (30); d) forming a second moisture-tight protection layer (38) covering the first layer (32) and the walls of each opening (34); and e) forming a color filter (40) in each opening (34), the second protection layer (38) being located between the porous layer (30) and the color filter (40) present in the opening (34).

The method further includes, at step c), the forming of a through groove (36) in the porous layer (30) totally surrounding the openings (34), the second protection layer (38) further covering at step d) the walls of the groove (36).

The method further includes the following steps: prior to step a), the forming of a plurality of photodetectors (12) inside and on top of the semiconductor substrate (10), the color filters (40) being formed at step e) covering the photodetectors (12); forming a plurality of microlenses (48) covering the color filters (40); and forming a third protection layer (52) over the plurality of microlenses (48) and over the first and second protection layers (32, 38) around the plurality of microlenses (48).

The semiconductor substrate (10) includes a second surface (10i) opposite to the first surface (10s), the method further includes the forming, prior to step a), of a hole (24) extending from the first surface (10s) to the second surface (10i) and of an electrically-conductive pad (20) including a first portion (20c) extending over the first surface (10s) and a second portion (20j) covering the flanks of the hole (24) and delimiting a gap (26) in the hole (24).

The method further includes, prior to step a), the forming of a resin block (28) in the gap (26), the porous layer (30) covering the electrically-conductive pad (20) and the resin block (28), and, after step e), the successive etching of the first protection layer (32), of the second protection layer (38), and of the porous layer (30) to expose the electrically-conductive pad (20) and the resin block (28), and the removal of the resin block (28).

The method further includes the forming of a guard ring and the electrically-conductive pad (20) forms part of the guard ring.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An image sensor comprising:
a semiconductor substrate comprising a first surface;
a porous layer made of an electrically-insulating and porous material on the first surface, the porous layer having a second surface opposite the first surface;
a plurality of openings through the porous layer;
a color filter in each opening;
a first moisture-tight protection layer covering the second surface of the porous layer; and
a second moisture-tight protection layer covering the first protection layer and a plurality of walls of each opening between the porous layer and the color filter in each opening.

2. The image sensor according to claim 1, wherein a porosity by volume of the porous material is in the range of 35% and 55%.

3. The image sensor according to claim 1, wherein the porous layer comprises a through groove entirely surrounding the openings, the second protection layer covering a plurality of walls of the groove.

4. The image sensor according to claim 1, further comprising:
a plurality of photodetectors in the semiconductor substrate, the color filters covering the photodetectors;
a plurality of microlenses covering the color filters; and
a third protection layer over the plurality of microlenses and over the first and second protection layers.

5. The image sensor according to claim 1, wherein the semiconductor substrate includes a second surface opposite to the first surface and at least one hole extending from the first surface to the second surface, the image sensor further including an electrically-conductive pad including a first portion extending over the first surface and a second portion covering sidewalls of the hole and delimiting a gap in the hole.

6. The image sensor according to claim 5, further comprising a guard ring, wherein the electrically-conductive pad forms part of the guard ring.

7. The image sensor according to claim 1, wherein a thickness of the porous layer is in the range of 400 nm and 900 nm.

8. A method of manufacturing an image sensor comprising:
forming a porous layer, made of an electrically-insulating and porous material, on a first surface of a semiconductor substrate;
forming a first moisture-tight protection layer covering the porous layer;
forming openings through the first protection layer and the porous layer;
forming a second moisture-tight protection layer covering the first layer and a plurality of walls of each opening; and
forming a color filter in each opening, the second protection layer being between the porous layer and the color filter in the opening.

9. The method according to claim 8, further comprising, during the forming the openings, forming a through groove in the porous layer entirely surrounding the openings, the second protection layer covering the walls of the groove during the forming the second protection layer.

10. The method according to claim 8, further comprising:
forming, prior to the forming the porous layer, a plurality of photodetectors inside and on top of the semiconductor substrate, the color filters covering the photodetectors during the forming the color filter in each opening;
forming a plurality of microlenses covering the color filters; and
forming a third protection layer over the plurality of microlenses and over the first and second protection layers.

11. The method according to claim 8, wherein the semiconductor substrate includes a second surface opposite to the first surface, the method further including forming, prior to the forming the porous layer, a hole extending from the first surface to the second surface, and an electrically-conductive pad including a first portion extending over the first surface and a second portion covering sidewalls of the hole and delimiting a gap in the hole.

12. The method according to claim 11, further comprising:
prior to the forming the porous layer, forming a resin block in the gap, the porous layer covering the electrically-conductive pad and the resin block; and
after the forming the openings, etching the first protection layer, the second protection layer, and the porous layer to expose the electrically-conductive pad and the resin block, and removing the resin block.

13. The method according to claim 11, further comprising forming a guard ring, wherein the electrically-conductive pad forms a part of the guard ring.

14. A device, comprising:
a semiconductor substrate having a first side opposite a second side along a first direction;
a plurality of photodetectors in the semiconductor substrate;
a first opening extending from the first side to the second side;
a first insulating layer entirely covering the first side and a plurality of sidewalls of the first opening;
a porous layer covering the first side and the first opening;
a first protection layer covering the porous layer;
a plurality of trenches extending along the first direction through the first protection layer, the porous layer, and the first insulating layer;
a second protection layer on the first protection layer and along a plurality of sidewalls of each trench; and
a color filter in each trench, each color filter being aligned with one of the plurality of photodetectors along the first direction.

15. The device according to claim 14, further comprising a second insulating layer directly on the first side and an opaque screen layer between the second insulating layer and the first insulating layer.

16. The device according to claim 14, further comprising a contacting pad in the first opening, the contacting pad including:
a first portion extending over the first side of the semiconductor substrate;
a second portion on the plurality of sidewalls of the first opening, the second portion extending along the first direction through a hole in the first insulating layer and being coplanar with the second side of the semiconductor substrate; and
a gap extending from the first side along the first direction into the first opening.

17. The device according to claim 14, wherein the first and second protection layers are moisture-tight.

18. The device according to claim 14, further comprising a groove extending along the first direction through the first protection layer, the porous layer, and the first insulating layer, a plurality of sidewalls of the groove being covered by the second protection layer.

19. The device according to claim 18, further comprising a resin layer on the second protection layer, on the color filters, and in the groove, the resin layer including a plurality of microlenses, each microlens being aligned with a respective one of the color filters and a respective one of the photodetectors along the first direction.

20. The device according to claim 19, further comprising a third protection layer covering the second protection layer, the resin layer, and the plurality of microlenses.
